(19) United States
(12) Patent Application Publication
(10) Pub. No.: US 2012/0007073 A1
(43) Pub. Date: Jan. 12, 2012

(54) Semiconductor Wafer Constructions, And Methods For Quality Testing Material Removal Procedures During Semiconductor Fabrication Processes

(76) Inventors: Anjum Mehta, Boise, ID (US); Shawn Lyonsmith, Boise, ID (US); Rajesh Kamana, Boise, ID (US); Tyler Hansen, Boise, ID (US); Amit Gupta, Boise, ID (US); Suresh Ramakrishnan, Boise, ID (US)

(21) Appl. No.: 12/830,732

(22) Filed: Jul. 6, 2010

(51) Int. Cl. H01L 23/48; H01L 21/66

(52) U.S. Cl. 257/48; 438/18; 257/E21.529; 257/E23.01

(57) ABSTRACT

Some embodiments include methods for quality testing material removal procedures. A test structure is formed to contain a pair of electrically conductive segments. The segments are the same relative to a detectable property as long as they are electrically connected, but becoming different relative to such property if they are disconnected from one another. A material is formed over the test structure, and across a region of a semiconductor substrate proximate to the test structure. The material is subjected to a procedure which removes at least some of it, and which fabricates a structure of an integrated circuit construction in the region proximate to the test structure. After the procedure, it is determined if the segments are the same relative to the detectable property.

### TECHNICAL FIELD

Semiconductor wafer constructions, and methods for quality testing material removal procedures during semiconductor fabrication processes.

### BACKGROUND

The term “semiconductor fabrication process” is utilized to describe any process which fabricates structures associated with a semiconductor substrate. Example semiconductor fabrication processes include processes utilized to form integrated circuitry, and processes utilized to form micro-electro-mechanical systems (MEMS).

Semiconductor fabrication processes often form multiple levels of structures over a supporting substrate. Common procedures utilized during formation of the various levels may include deposition sequences, patterning sequences, and material removal sequences. The material removal may be accomplished utilizing various etches and/or chemical-mechanical polishing (CMP).

A problem that can occur during material removal is that it can be difficult to determine if the desired amount of material has been removed. If too little of the material is removed, the excess remaining material may destroy operation of resulting structures, and/or may create complications during subsequent fabrication of additional levels of structures. If too much of the material is removed, such may destroy operation of resulting structures, and/or may create problems in underlying levels and/or in subsequent levels.

Often semiconductor fabrication processes are utilized to simultaneously produce structures across a plurality of semiconductor die locations associated with a semiconductor wafer in order to cost-effectively produce a plurality of identical semiconductor dies. The wafer may be cut (which is sometimes referred to as dicing) to separate the individual dies from one another.

A problem that may occur during material removal stages of semiconductor fabrication processes is that the material removal may not be uniform across the entirety of the semiconductor wafer. Accordingly, a desired amount of material may be removed from some locations of the wafer; while too much, or too little, material is removed from other locations of the wafer. The lack of uniformity can be problematic from die to die across a wafer, as well as within a single die.

It is often difficult to quickly ascertain if the appropriate amount of material has been removed during a material removal stage of a semiconductor fabrication process. It can be particularly difficult to quickly ascertain which of the individual die locations across a semiconductor wafer have had an appropriate amount of material removed, and which have had too much or too little material removed. It can also be difficult to quickly ascertain if there is desired uniformity of material removal within individual dice. Accordingly, it would be desirable to develop new methods for quality testing material removal procedures of semiconductor fabrication processes.

### BRIEF DESCRIPTION OF THE DRAWINGS

FIGS. 1 and 2 are a diagrammatic cross-sectional side view, and a top view, respectively, of a semiconductor construction comprising a pair of electrically conductive lines with different electrical discharge capabilities. The cross-sectional view of FIG. 1 is along the line 1-1 of FIG. 2.

FIGS. 3 and 4 are a diagrammatic cross-sectional side view, and a top view, respectively, of the semiconductor construction of FIGS. 1 and 2 showing different behavior of the lines when the lines are subjected to an energetic particle beam (for instance, an electron beam). The cross-sectional view of FIG. 3 is along the line 3-3 of FIG. 4.

FIGS. 5 and 6 are a diagrammatic cross-sectional side view, and a top view, respectively, of a semiconductor construction comprising an example embodiment test structure. The cross-sectional view of FIG. 5 is along the line 5-5 of FIG. 6.

FIGS. 7 and 8 are top views of the semiconductor construction of FIGS. 5 and 6 illustrating a pair of example embodiment modes of operation of the test structure.

FIG. 9 is a diagrammatic cross-sectional side view of another example embodiment test structure.

FIG. 10 is a view of the test structure of FIG. 9 in an example mode of operation.

FIG. 11 is a top view of a semiconductor wafer, and illustrates die locations and scribe regions between the die locations.

FIG. 12 is a diagrammatic cross-sectional side view of a semiconductor wafer having a material thereover which is to be removed with chemical-mechanical polishing.

FIG. 13 shows the wafer of FIG. 12 after chemical-mechanical polishing, and shows an under-polish problem.

FIG. 14 shows the wafer of FIG. 12 after chemical-mechanical polishing, and shows an over-polish problem.

FIGS. 15-17 are diagrammatic cross-sectional side views of portions of a semiconductor wafer, and show a test structure being utilized to detect a desired polish (FIG. 16), and an under-polish (FIG. 17).

FIGS. 18-20 are diagrammatic cross-sectional side views of portions of a semiconductor wafer, and show a test structure being utilized to detect a desired polish (FIG. 19), and an over-polish (FIG. 20).

FIG. 21 shows diagrammatic cross-sectional side views of portions of a semiconductor wafer, and shows a plurality of test structures being utilized proximate a region that is to have numerous materials removed during a process for fabrication of integrated circuitry.

FIGS. 22-24 are diagrammatic cross-sectional side views of a portion of a semiconductor wafer, and show another embodiment test structure being utilized to detect a desired polish (FIG. 23), and an under-polish (FIG. 24).

### DETAILED DESCRIPTION OF THE ILLUSTRATED EMBODIMENTS

Some embodiments include methods in which test structures are provided at various locations across a semiconductor substrate during a semiconductor fabrication process, and in which the test structures are utilized for quality testing material removal procedures of the fabrication process. The test structures may include a pair of electrically conductive segments. The segments may be constructed so that they are the same in a detectable property as long as they are electrically connected to one another, but become different relative to such property if they become disconnected from one another.

In some embodiments conductive material is provided across the segments and subjected to a polish. If the conductive material remains over the segments after the polish, it will electrically connect the segments to one another. If the conductive material is removed from over the segments during the polish, the segments will become electrically disconnected. This may be particularly useful for determining if there has been appropriate line separation in a damascene process.

In some embodiments an electrical jumper is provided across the segments as part of the test structure. The segments may be constructed so that they are the same in a detectable property as long as the jumper connects them, but become different relative to such property if the jumper becomes broken. In operation, a material may be provided over a test structure and subjected to a removal process which utilizes conditions capable of both removing material and breaking the jumper. After the removal process is completed, it can be determined if the electrically conductive segments remain the same as one another relative to the detectable property. If they do, the jumper was not broken and the removal process therefore did not penetrate all the way through the material to expose the jumper to the conditions which would break the jumper. In contrast, if the conductive segments do not remain the same as one another relative to the detectable property, the jumper was broken.

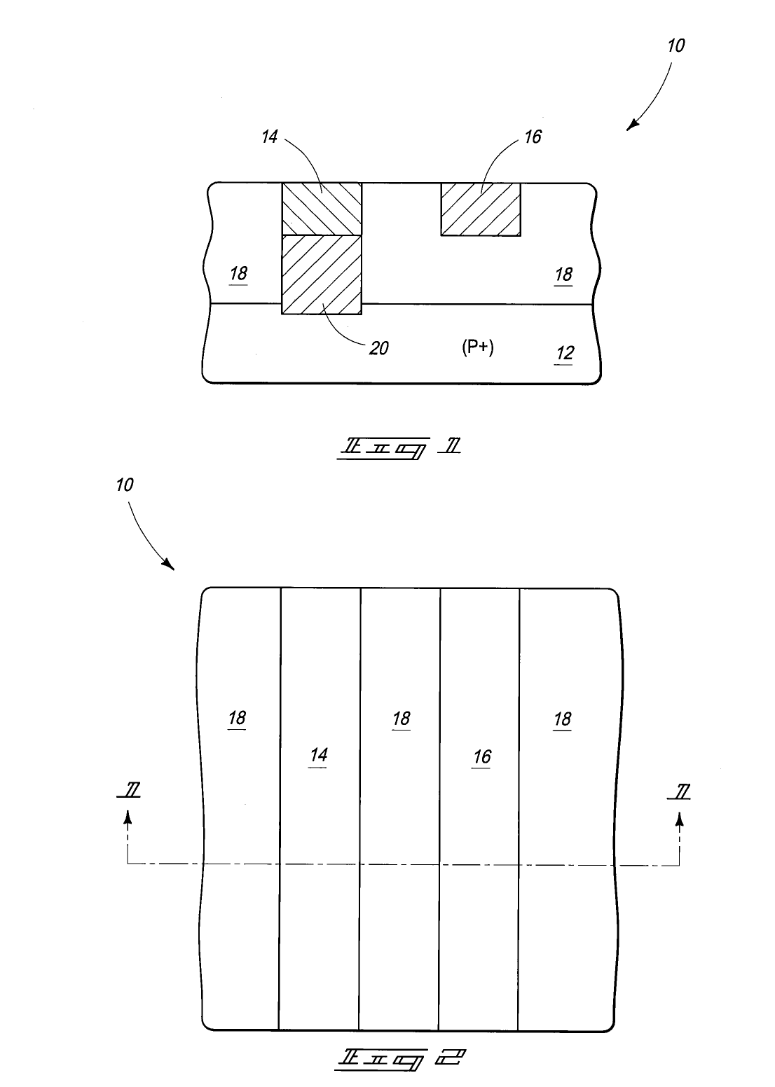

Example embodiment test structures may utilize conductive segments which differ from one another relative to the quantity of secondary electron emission induced by an energetic particle beam (for instance, an electron beam). Such test structures are described with reference to FIGS. 1-6.

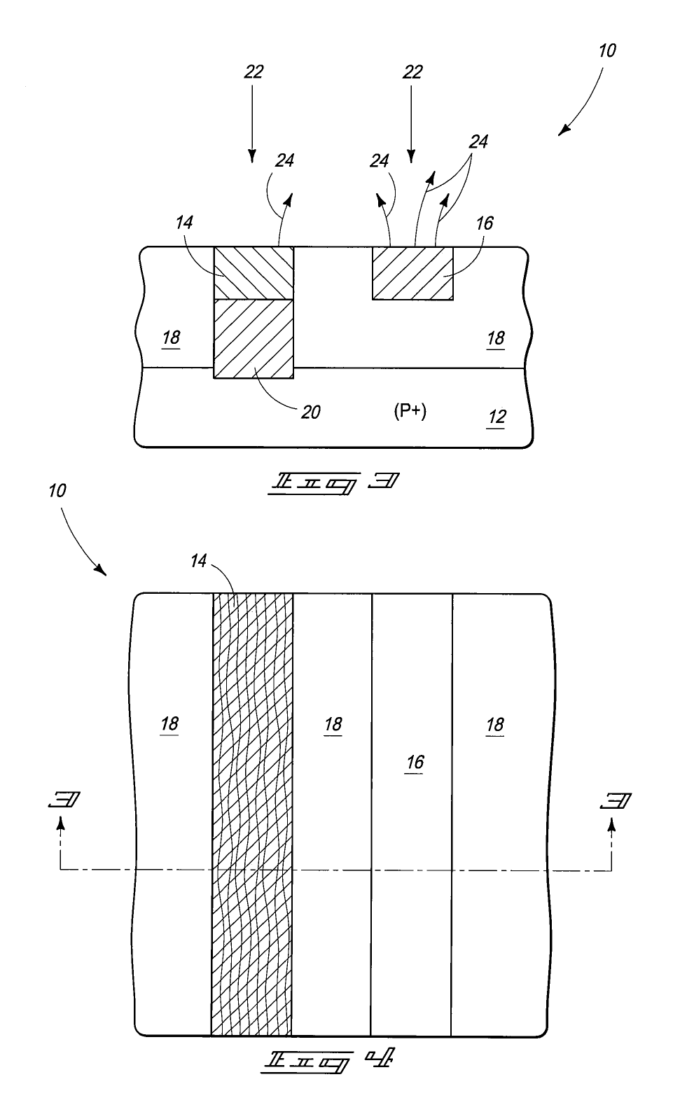

Referring to FIGS. 1 and 2, such illustrate a semiconductor construction 10 having a pair of electrically conductive segments 14 and 16 supported by a semiconductor base 12.

Base 12 may comprise, consist essentially of, or consist of monocrystalline silicon, and may be referred to as a semiconductor substrate, or as a portion of a semiconductor substrate. The terms “semiconductive substrate,” “semiconductor construction” and “semiconductor substrate” mean any construction comprising semiconductive material, including, but not limited to, bulk semiconductive materials such as a semiconductive wafer (either alone or in assemblies comprising other materials), and semiconductive material layers (either alone or in assemblies comprising other materials). The term “substrate” refers to any supporting structure, including, but not limited to, the semiconductive substrates described above. Although base 12 is shown to be homogenous, the base may comprise numerous layers in some embodiments. For instance, base 12 may correspond to a semiconductor substrate containing one or more layers associated with integrated circuit fabrication. Such layers may correspond to one or more of refractory metal layers, barrier layers, diffusion layers, insulator layers, etc. In the shown embodiment base 12 comprises a region heavily doped with p-type dopant. In other embodiments the illustrated region may be heavily doped with n-type dopant.

An electrically insulative material 18 is over base 12; and the segments 14 and 16 extend into such electrically insulative material. The electrically insulative material 18 may comprise any suitable composition or combination of compositions, and in some embodiments may comprise one or more of silicon dioxide, silicon nitride, and doped silicon oxide (e.g., borophosphosilicate glass, phosphosilicate glass, fluorosilicate glass, etc.).

The electrically conductive segment 14 is connected to the illustrated doped region of base 12 through an electrical interconnect 20. The electrical interconnect is shown to be a separate structure from segment 14. In other embodiments the interconnect 20 and segment 14 may be a common structure. The interconnect 20 provides an electron discharge path between segment 14 and the doped region of semiconductor base 12. Segment 16 has no equivalent electron discharge path.

The top view of FIG. 2 shows the segments 14 and 16 to be parallel lines in the illustrated example embodiment.

The segments 14 and 16 may be the same chemical composition as one another; and in some embodiments may comprise, consist essentially of, or consist of one or more of various metals (for instance, tungsten, tantalum, ruthenium, copper, etc.) and/or metal-containing compositions (for instance, metal nitrides, metal silicides, etc.).

Referring to FIG. 3, segments 14 and 16 are shown being exposed to an energetic particle beam (for instance, an electron beam) 22. The beam induces emission of secondary electrons 24 from segments 14 and 16. However, there is a difference between the number of secondary electrons emitted from segment 16 relative to the number emitted from segment 14 due to segment 14 having a better electron discharge path (directly into the heavily-doped region of base 12) than segment 16, and also due to the imaging mode used. FIG. 3 shows retarding mode (negative mode) imaging where a higher quantity of secondary electrons is emitted from segment 16 (relatively bad electron discharge path) than from segment 14 (good electron discharge path). If extraction mode (positive mode) imaging is used, then the number of secondary electrons emitted from segment 14 would be higher than the number emitted from segment 16.

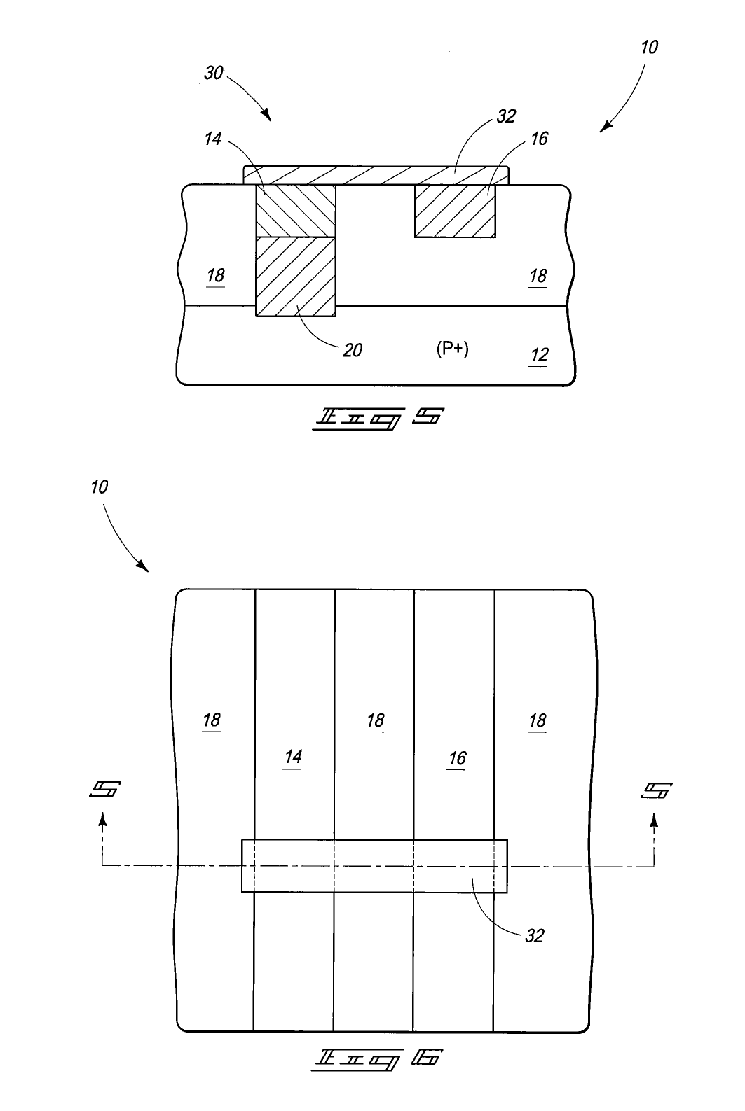

FIG. 4 shows a top view of construction 10 as it is exposed to the electron beam 22 (beam 22 is shown in FIG. 3, but not in FIG. 4), and shows that there is a detectable difference in contrast between segment 14 and segment 16 due to the difference in the quantity of secondary electron emission from such segments. Specifically, in the shown embodiment segment 16 appears “lit up” due to the secondary electron emission, while segment 14 appears dark (the darkness of segment 14 is represented by cross-hatching of segment 14). In some embodiments the difference between segments 14 and 16 may be visually detected by an observer without special optics, and in other embodiments the difference between the segments may be detected through the utilization of special optics and/or other equipment.

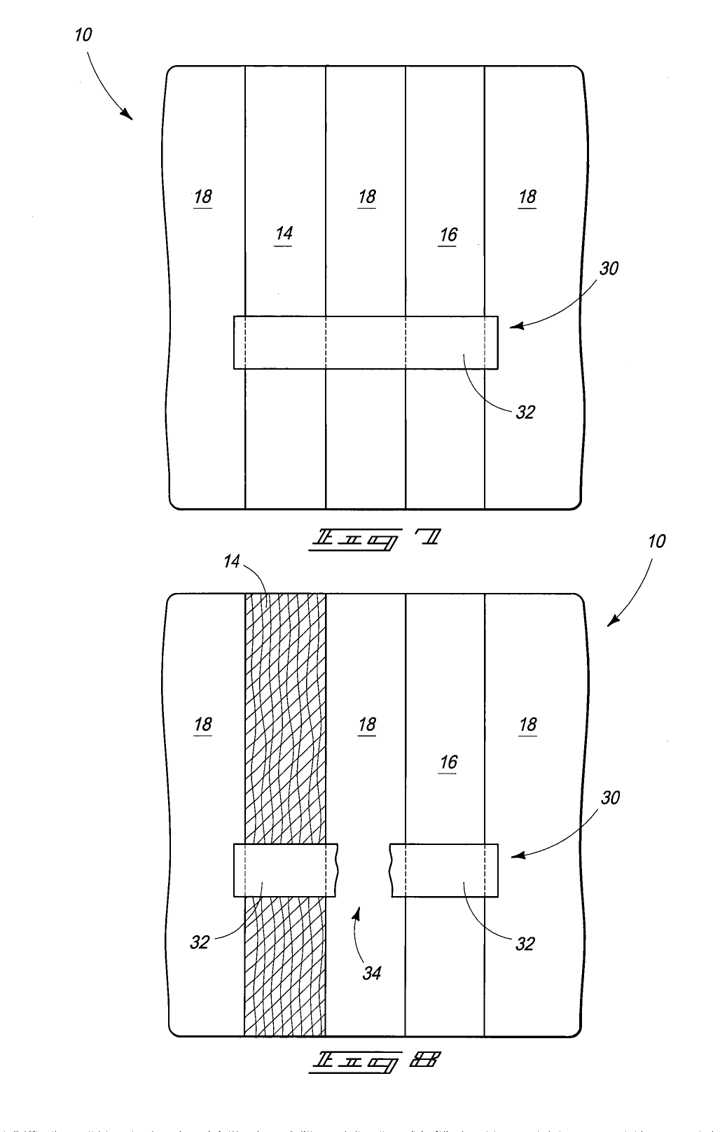

FIGS. 5 and 6 show a test structure 30 comprising the segments 14 and 16 of FIGS. 1-4 in combination with an electrical jumper 32. The jumper 32 extends across segments 14 and 16, and electrically connects the segments to one another. The illustrated jumper is a thin strap that extends laterally outward beyond each of the segments 14 and 16. In other embodiments the jumper may have other configurations. Jumper 32 may be formed of any suitable electrically conductive material, and in some embodiments may comprise, consist essentially of, or consist of one or more of various metals, metal-containing compositions, and conductively-doped semiconductor materials (for instance, conductively-doped silicon, conductively-doped germanium, etc.).

The jumper 32 provides an electrical path between segments 14 and 16, and thus the segments 14 and 16 may behave identical to one another relative to secondary electron emission induced by an energetic particle beam while the jumper is in place. However, once the jumper is broken the segment 16 will lose the discharge path to the doped region of substrate 12, and will again become distinguishable from segment 14 relative to the secondary electron emission induced by the energetic particle beam (for instance, an electron beam).

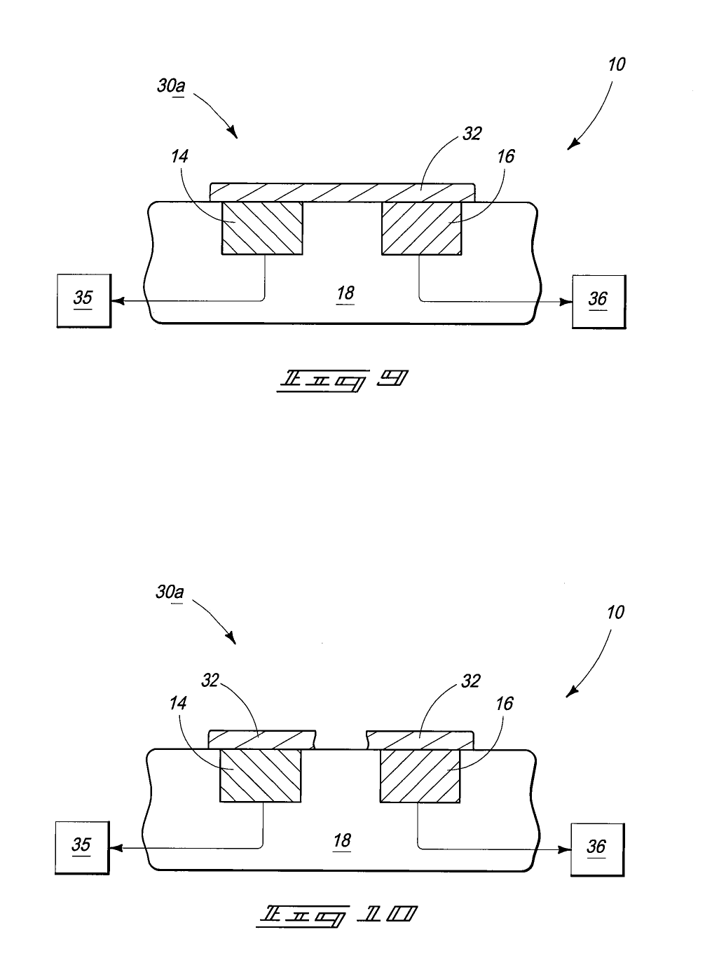

FIGS. 7 and 8 show test structure 30 exposed to an electron beam (not shown) in a mode in which jumper 32 is intact (FIG. 7) and a mode in which the jumper is broken (FIG. 8). The segments 14 and 16 are the same as one another in appearance in FIG. 7, while in FIG. 8 there is a readily-apparent difference in appearance between the segments 14 and 16.

The break in the jumper 32 is represented in FIG. 8 as the formation of a gap 34 through the jumper. In other embodiments the break may result from complete removal of the jumper from over the segments 14 and 16 (such as would occur, for example, if the jumper is removed from over segments 14 and 16 by CMP).

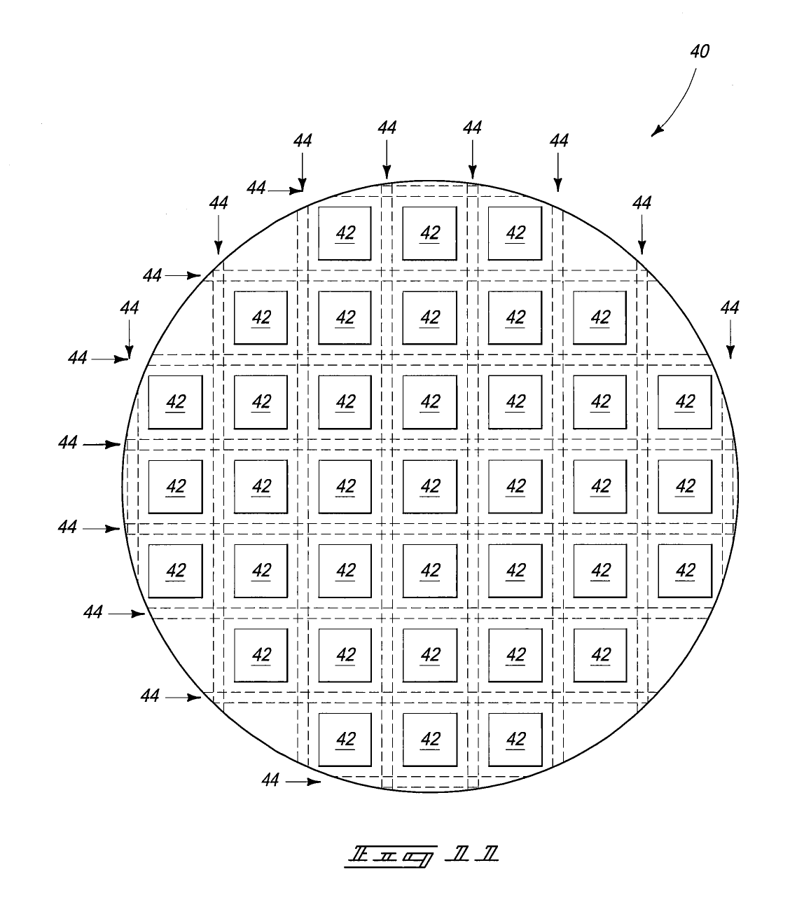

The above-discussed test structure 30 utilizes secondary electron emission to determine if jumper 32 is intact. Analogous test structures may be constructed which utilize other methods for determining the integrity of jumper 32 across the electrically conductive segments 14 and 16. FIG. 9 shows a test structure 30a comprising the segments 14 and 16, and the electrically conductive jumper 32 electrically connecting the segments to one another. The segment 14 is shown to be electrically connected to first circuitry 35, and the segment 16 is shown to be electrically connected to second circuitry 36. In operation, the first circuitry 35 may be configured to hold segment 14 at a first electrical state, and the circuitry 36 may be configured to detect an electrical state of segment 16. The segment 16 may be electrically floated, or otherwise configured so that the electrical state (for instance, voltage) of segment 16 changes based upon whether jumper 32 is intact or broken.

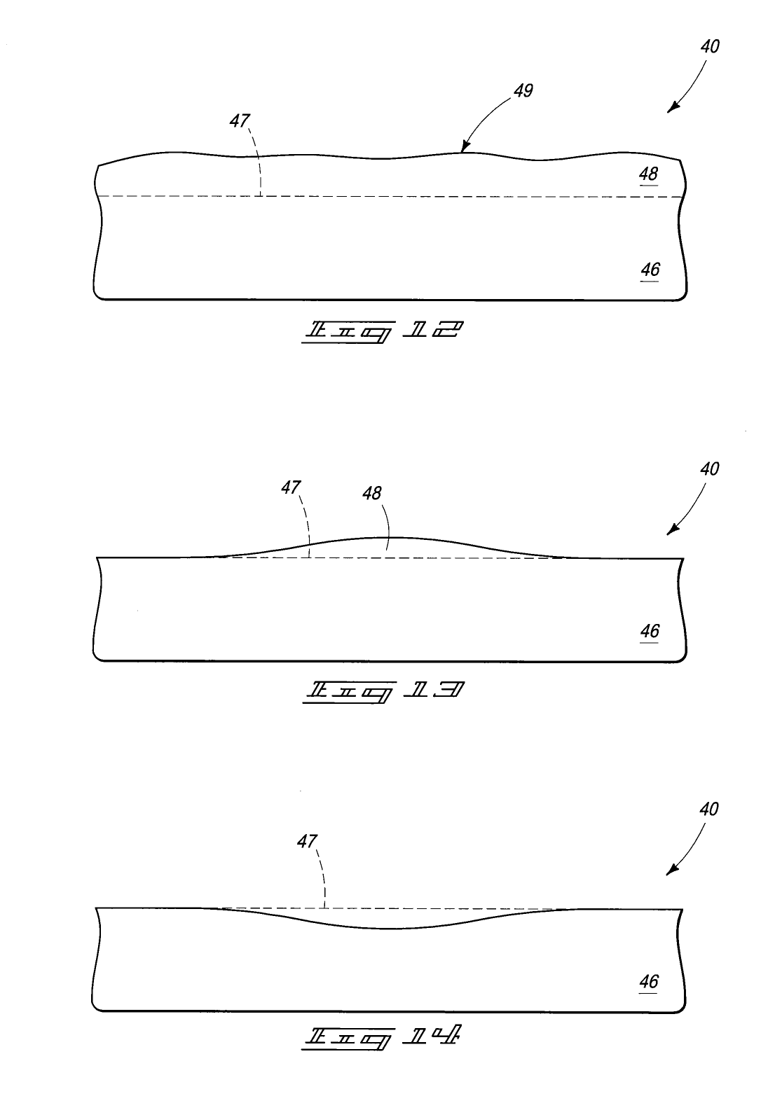

The operational mode of FIG. 9 shows jumper 32 intact, and accordingly segments 14 and 16 are in the same electrical state as one another. In contrast, FIG. 10 shows test structure 30a in an operational mode in which jumper 32 is broken, and thus segment 16 can be in electrical state different from that of segment 14. Circuitry 36 can be utilized to detect such change in the electrical state of segment 16 to thereby indicate the loss of integrity of jumper 32.

The various test structures of FIGS. 1-10 may be utilized for quality testing material removing procedures during semiconductor fabrication processes. FIG. 11 shows a semiconductor wafer 40 which may be utilized during a semiconductor fabrication process. The wafer has a plurality of die locations 42, and a plurality of scribe regions 44 between the die locations. In operation, semiconductor devices (for instance, integrated circuitry and/or MEMS) are formed across the die locations, and subsequently the wafer is sawed or otherwise separated along the scribe regions to separate the individual die from one another. Thus, the scribe regions may be considered to be throw-away parts of the wafer. In some embodiments at least some of the test structures utilized for quality testing various procedures of a semiconductor fabrication process are formed in the scribe regions; and in some embodiments all of the test structures having configurations of the type described above with reference to FIGS. 1-10 are formed in the scribe regions. Accordingly, the test structures may be formed over throw-away regions of a semiconductor wafer, rather than consuming valuable real estate of the die locations.

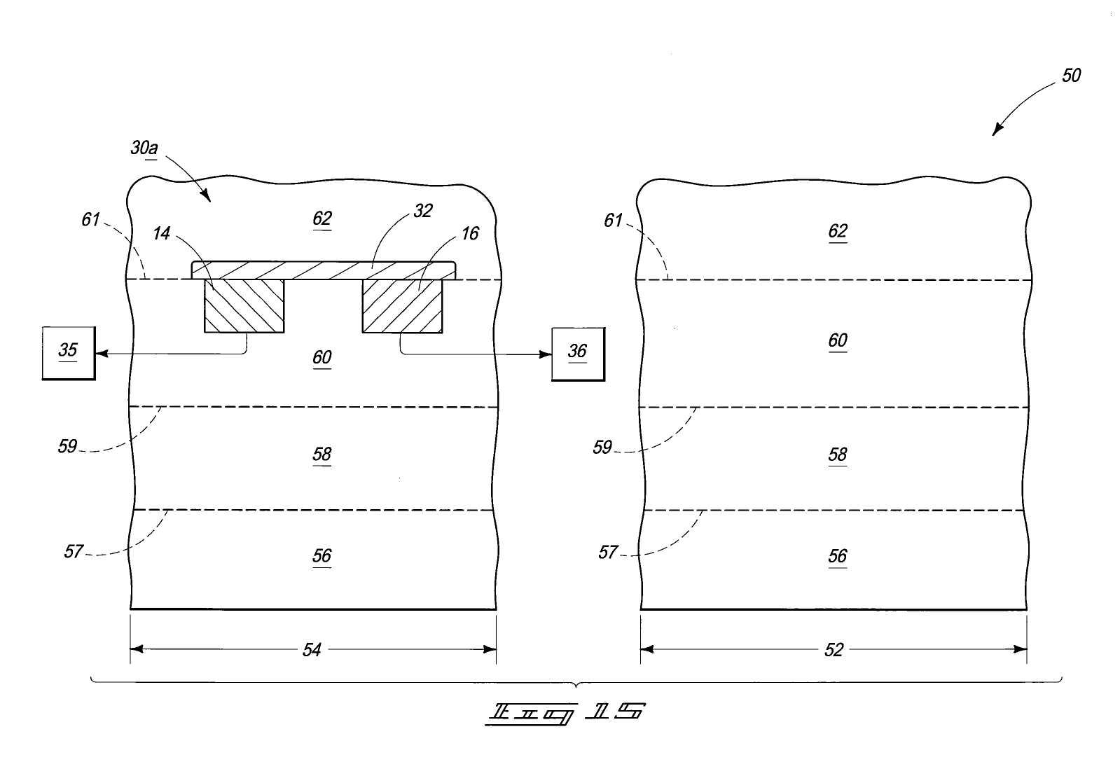

As discussed above in the “Background” section, it can be difficult to remove material uniformly from across a semiconductor wafer during a semiconductor fabrication process. FIGS. 12-14 show wafer 40 at various stages of a semiconductor fabrication process, and illustrate example problems that may occur. The die locations and scribe regions are not shown in FIGS. 12-14 in order to simplify the drawings.

FIG. 12 shows a material 48 formed over a semiconductor substrate 46. The material 48 has a non-planar upper surface 49. It can be desired to remove at least some of material 48, and to simultaneously planarize the upper surface. Such can be accomplished utilizing CMP. A dashed line 47 is provided in FIG. 12 to illustrate a desired location of a planarized upper surface which is to be formed by CMP.

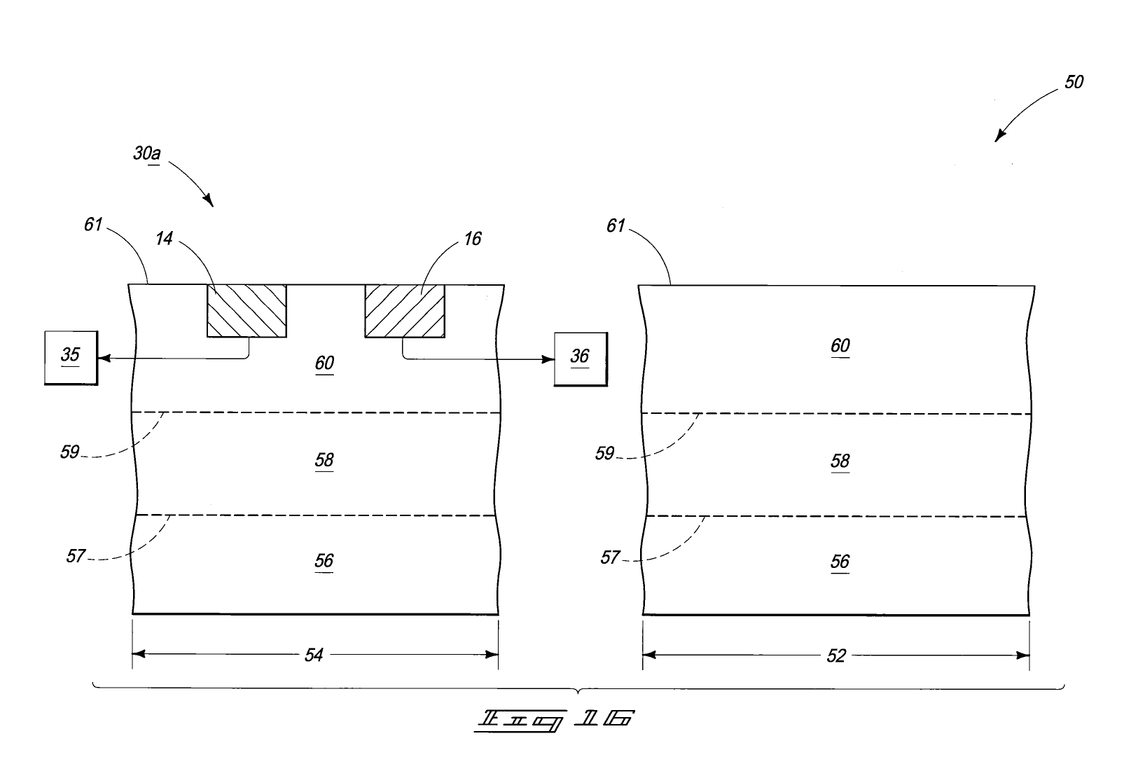

FIG. 13 shows construction 40 after CMP and illustrates an under-etch (or dome) problem that can occur. The problem is exaggerated in FIG. 13 to assist in illustrating the problem. The nature of the problem is that material 48 has not been uniformly removed down to the desired level of dashed line 47, and accordingly too much of material 48 remains The extent of the problem varies across wafer 40. Accordingly, some of the dies across the wafer may be usable, while others are not. Also, individual dies may have some usable regions and some unusable regions. FIG. 13 is utilized to generically illustrate doming type problems that can occur across numerous dies of a wafer, and/or within a single die. A problem in the prior art is that it can be difficult to quickly ascertain which of the dies across the wafer may be usable, and/or to determine which regions of individual dies are usable. A specific problem can be to determine if there is desired line isolation in damascene processes. In embodiments for testing for appropriate line separation in damascene process, the “jumper” may not be intentionally created, but may instead correspond to stringers or “jumpers” resulting from incomplete removal of conductive material (as discussed below with reference to FIGS. 22-24). In some embodiments the problems associated with determining etch uniformity and/or line isolation are addressed by providing various test structures of the types shown in FIGS. 1-10 in the scribe regions across a semiconductor substrate. Such test structures may then be utilized to determine which regions of the substrate had appropriate polishing, and which did not.

FIG. 14 shows construction 40 after CMP and illustrates an over-etch (or bowl) problem that can occur. The problem is exaggerated in FIG. 14 to assist in illustrating the problem. The nature of the problem is that material 48 has been over-aggressively removed from some regions, and accordingly too much material has been removed so that the polishing penetrates through level 47 at some regions of the wafer. The extent of the problem varies across wafer 40. Accordingly, some of the dies across the wafer may be usable, while others are not. Also, individual dies may have some usable regions and some unusable regions. FIG. 14 is utilized to generically illustrate dishing/erosion type problems that can occur across numerous dies of a wafer, and/or within a single die. In some embodiments various test structures of the types shown in FIGS. 1-10 may be provided in the scribe regions across a semiconductor substrate, and such test structures may be utilized to determine which regions of the substrate were over-polished, and which were not.

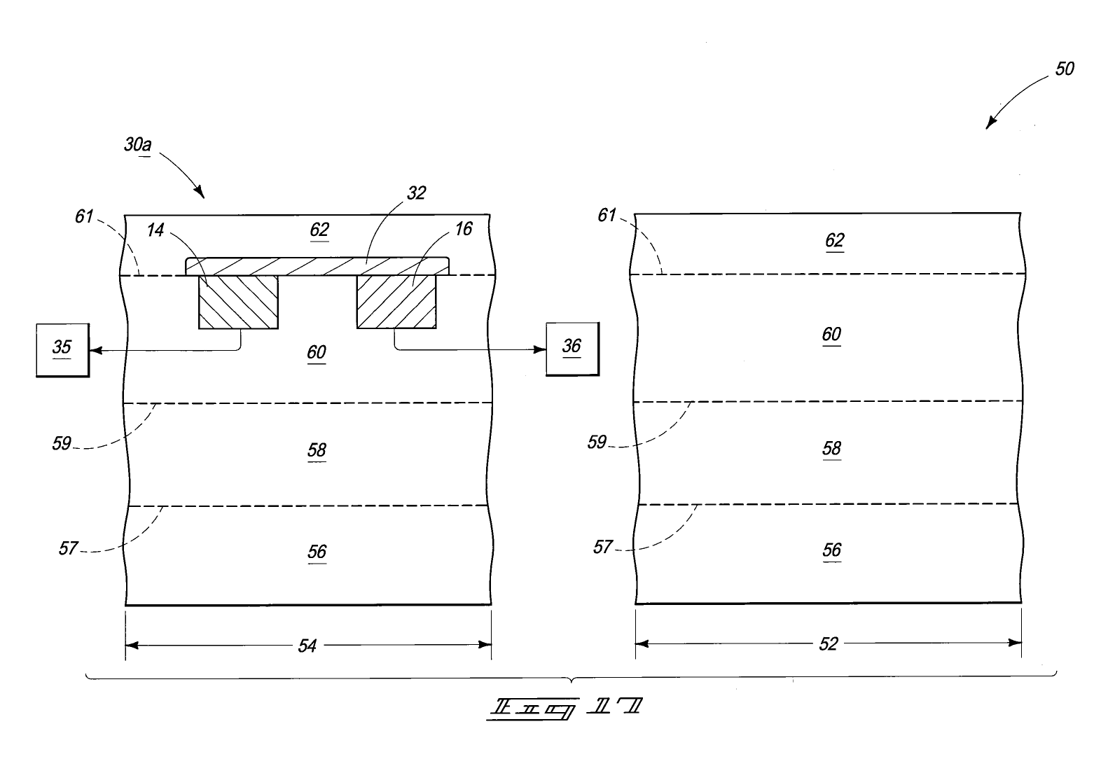

Example methods for utilizing the test structures are described with reference to FIGS. 15-24.

FIG. 15 shows a pair of regions 52 and 54 of a semiconductor construction 50. The semiconductor construction includes a semiconductor substrate 56 having various levels 58, 60 and 62 fabricated thereover. Dashed lines 57, 59 and 61 are utilized to diagrammatically illustrate boundaries between the levels. The levels may correspond to different levels of integrated circuit structures in some embodiments.

The levels 58, 60 and 62 may be considered to form a first stack of materials over region 52, and to form a second stack of materials over region 54. The second stack of materials is identical to the first stack materials, except that a test structure 30a is within the second stack of materials. Although the test structure is shown to be a structure 30a of the type described in FIGS. 9 and 10, in other embodiments the test structure may be a structure 30 of the type described in FIGS. 7 and 8 (for instance, circuitry 36 may be omitted, and circuitry 35 may be an electron discharge path to the underlying substrate), or a test structure without a jumper (as described below with reference to FIGS. 22-24).

In some embodiments region 54 may correspond to a scribe region of a semiconductor wafer, and region 52 may be part of a die location. In other embodiments, both of regions 54 and 52 may be part of a die location. If region 54 is part of a scribe region, the test structure will be destroyed when the wafer is cut along such scribe region. Regardless of whether the test structure 30a is associated with a scribe region, the test structure may be utilized solely for quality testing a material removal procedure. Thus, the test structure 30a may have no function in a finished construction formed through a semiconductor fabrication process in some embodiments.

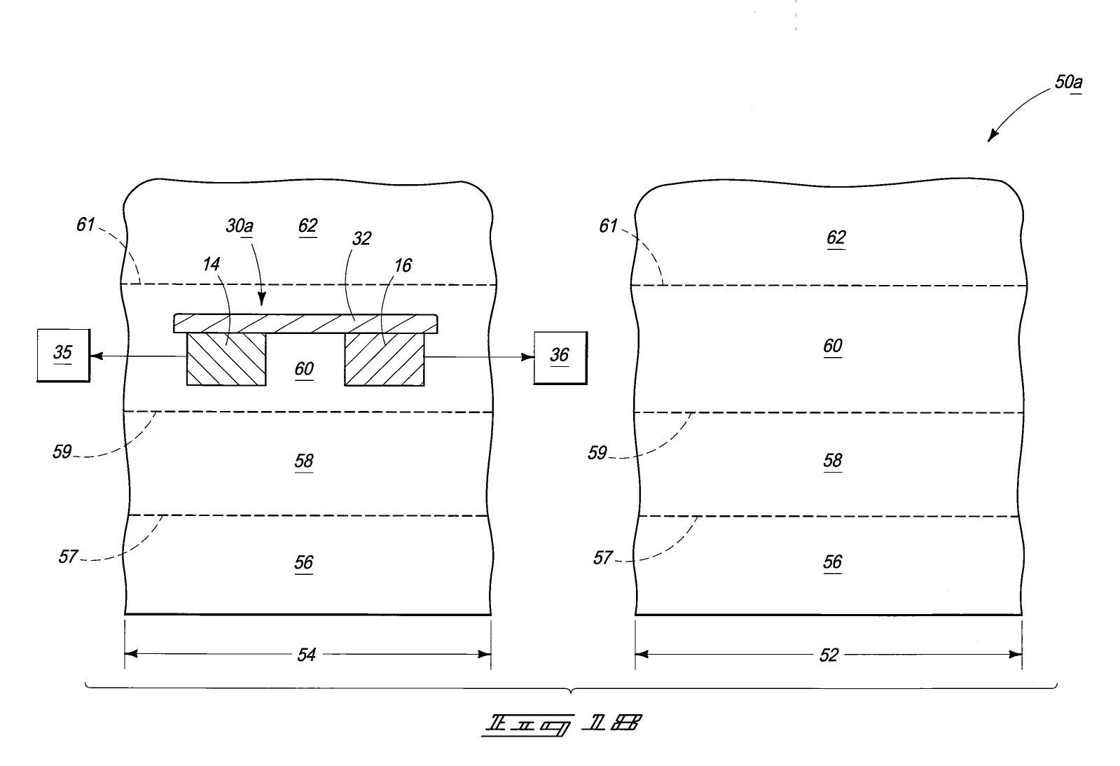

The level 62 comprises a material which is formed over the test structure and across the region 52 proximate to the test structure. It may be desired to remove level 62 in subsequent processing to form a planarized surface along the top of level 60 (i.e., at the level of boundary 61). FIGS. 16 and 17 show results of an etch (for instance, CMP) that creates the desired planarized surface at the desired level of boundary 61 (FIG. 16), and of an etch which under-removes material 62 (FIG. 17). The etch that reaches the desired level (FIG. 16) removes the jumper 32 (FIG. 15), while the etch that does not reach the desired level (FIG. 17) does not remove such jumper. Accordingly, a determination of whether segments 14 and 16 are in the same state as one another (which would indicate that the jumper 32 remains) or not (which would indicate that the jumper 32 has been broken) may be utilized to ascertain if the etch has penetrated entirely through material 62. Thus, the test structure 30a may be utilized to quality-test a material removal procedure during a semiconductor fabrication process, and in the shown embodiment is utilized to quality-test whether an etch has entirely removed material 62.

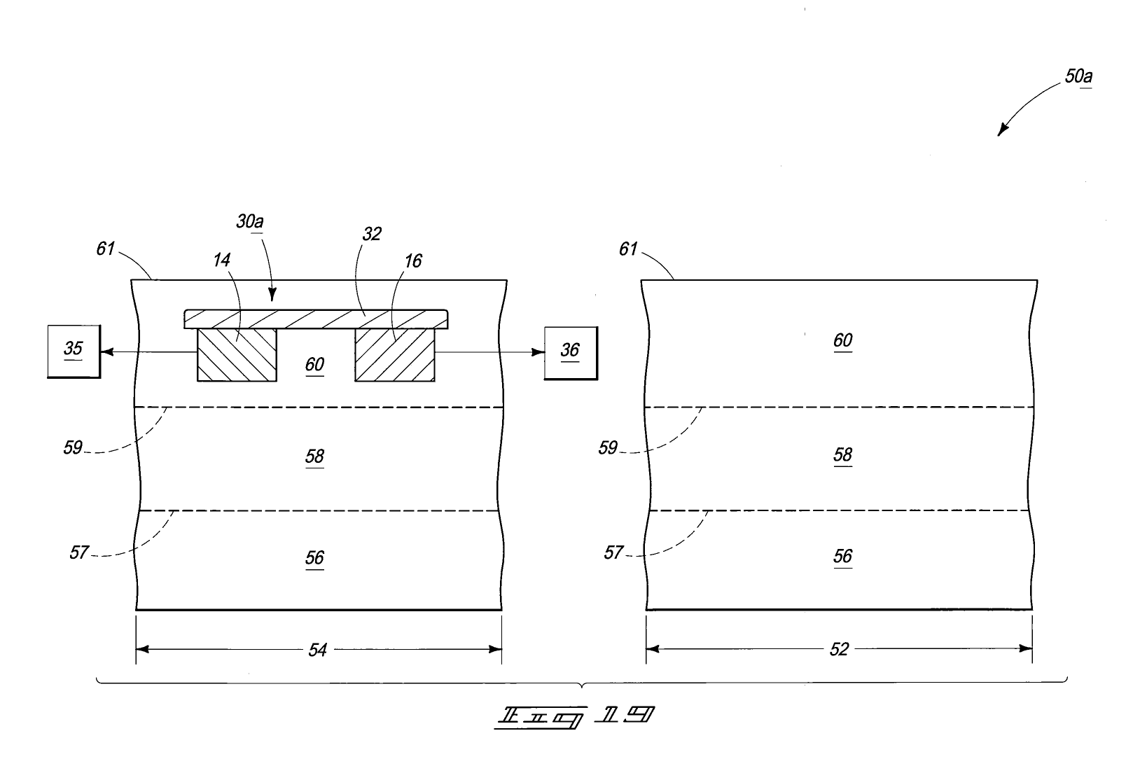

FIGS. 15-17 illustrate a process in which a test structure is utilized to detect under-polishing. In other embodiments, the same test structure may be utilized to detect over-polishing. An example embodiment in which a test structure is utilized to detect over-polishing is described with reference to FIGS. 18-20. In referring to FIGS. 18-20, the same numbering will be used as was utilized above in describing FIGS. 15-17, where appropriate.

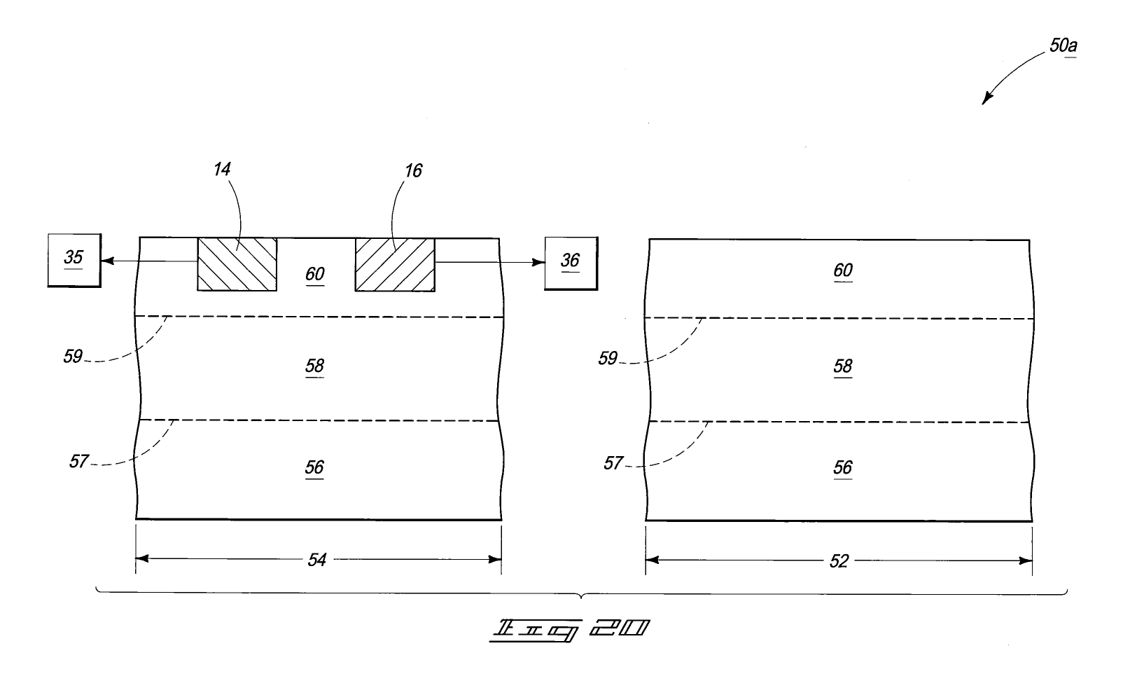

FIG. 18 shows a semiconductor construction 50a having the pair of regions 52 and 54. The construction 50a includes the semiconductor substrate 56, and the levels 58, 60 and 62 fabricated over the substrate. The construction of FIG. 18 is similar to that of FIG. 15, except that test structure 30a is formed so that jumper 32 is beneath the level of boundary 61 in FIG. 18. Thus, the test structure of FIG. 18 may be utilized to determine if an etch penetrates through boundary 61, as shown in FIGS. 19 and 20.

FIG. 19 shows results of an etch (for instance, CMP) that creates the desired planarized surface at the desired level of boundary 61. The etch that does not break the jumper 32. In contrast, FIG. 20 shows the results of an etch which penetrates through boundary 61 and removes the jumper 32. Accordingly, a determination of whether segments 14 and 16 are in the same state as one another (which would indicate that the jumper 32 remains) or not (which would indicate that the jumper 32 has been broken) may be utilized to ascertain if the etch has over-penetrated and passed through boundary 61. Thus, the test structure 30a may be utilized to quality-test a material removal procedure during a semiconductor fabrication process, and in the shown embodiment is utilized to quality-test whether an etch has penetrated the level of boundary 61.

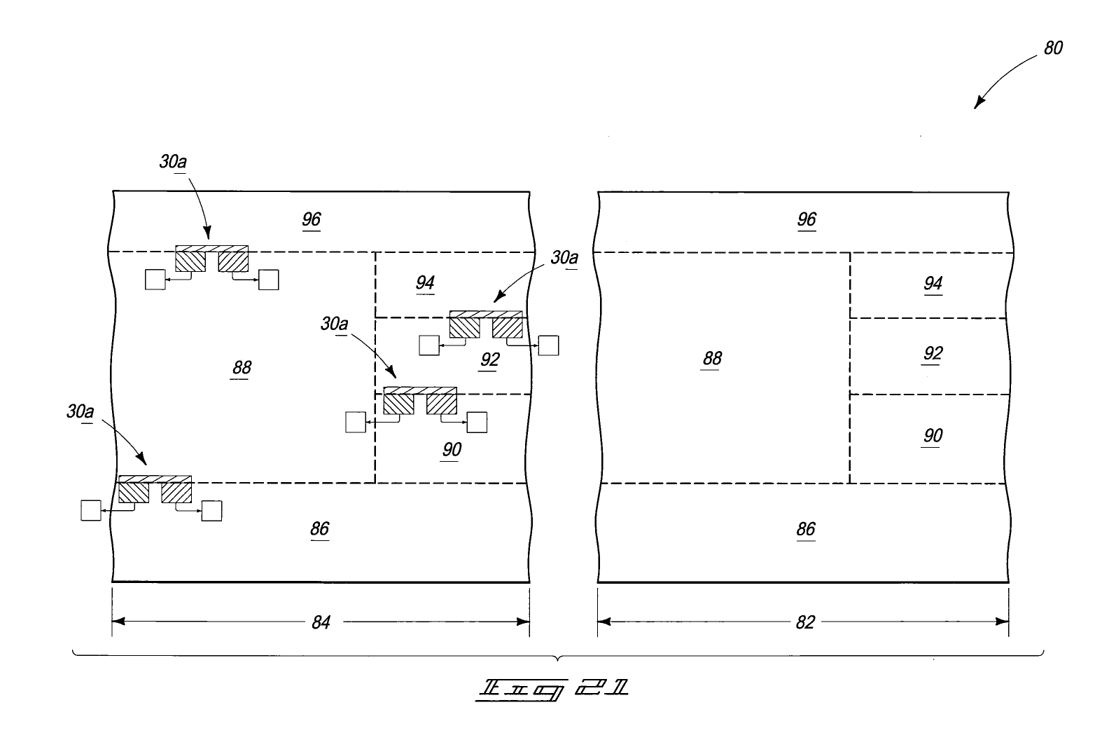

The embodiments of FIGS. 15-20 show individual test structures being utilized for detecting under-etch or over-etch. In some embodiments, multiple test structures may be provided within a region of a semiconductor construction to ascertain the quality of multiple material removal procedures. For instance, FIG. 21 shows a semiconductor construction 80 comprising a pair of regions 82 and 84. A variety of stacks of materials are within the regions 82 and 84; with such stacks including materials 86, 88, 90, 92, 94 and 96. Dashed lines are provided to diagrammatically illustrate boundaries between the various materials. The stacks within region 82 correspond to stacks that are to be patterned during integrated circuit fabrication. Region 84 is a testing region, and the stacks within such region are provided to replicate the stacks in region 82. A plurality of test structures 30a are provided throughout the testing region 84 (individual components of the test structures 30a are not labeled in FIG. 21 in order to simplify the drawing, but would be the same as the components shown and described with reference to FIGS. 9 and 10). Although the test structures are shown as the structures 30a of FIGS. 9 and 10, in some embodiments at least some of the test structures may correspond to structures 30 of the type described with reference to FIGS. 5-8, and/or to structures of the type described below with reference to FIGS. 22-24. Although only a single test structure is shown at each of the various levels in testing region 84, in some embodiments multiple test structures may be provided at individual levels. For instance, test structures for detecting under-polish and test structures for detecting over-polish may both be provided at an individual level.

During a semiconductor fabrication process, multiple material removal procedures may occur relative to region 82, and such steps may be simultaneously conducted relative to testing region 84. The testing region 84 may then be utilized to ascertain the quality of the various material removal procedures by determining if various jumpers of the testing structures 30a have been broken during the material removal procedures.

The testing region 84 may be provided in any suitable location of a semiconductor wafer during a semiconductor fabrication process. In some embodiments region 82 of FIG. 21 may correspond to a die location of a wafer (for instance, a location 42 of the wafer of FIG. 11), and multiple testing regions may be provided within the scribe regions of the wafer (for instance, the regions 44 of the wafer of FIG. 11).

The testing structures of FIGS. 5-21 had patterned electrical jumpers 32 provided over the segments 14 and 16; and the determination of whether or not the segments were in the same state as one another was utilized to ascertain if the jumper had been broken during an etch process. In some embodiments conductive material may be provided over segments 14 and 16 and subjected to etching (such as polishing), and the conductive material itself may function as the jumper so that a separate patterned jumper may be omitted from a testing structure. FIGS. 22-24 show an example embodiment method for utilizing a test structure which omits the separately patterned jumper 32 of the previously-described embodiments. Identical numbering will be used to describe the embodiment of FIGS. 22-24 as was used above for describing the embodiments of FIGS. 5-21, where appropriate.

FIG. 22 shows a semiconductor construction 100 having a substrate 102, and a testing structure 104 supported by the substrate. The test structure includes the segments 14 and 16 electrically connected to the first circuitry 35 and the second circuitry 36, respectively. Although the test structure is shown to be a structure analogous to the type described in FIGS. 9 and 10, in other embodiments the test structure may be analogous to the type described in FIGS. 7 and 8 (for instance, circuitry 36 may be omitted, and circuitry 35 may be an electron discharge path to the underlying substrate).

An electrically conductive material 106 is formed across the test structure. In some embodiments, the electrically conductive material may comprise a composition that is to be removed from over substrate 102 by CMP. For instance, the material 106 may be a metal-containing material utilized in a damascene fill process at location of a semiconductor wafer proximate to the test structure 104. In some embodiments the test structure 104 may be provided in a scribe location of a wafer analogous to the test structures described with reference to FIGS. 15-21.

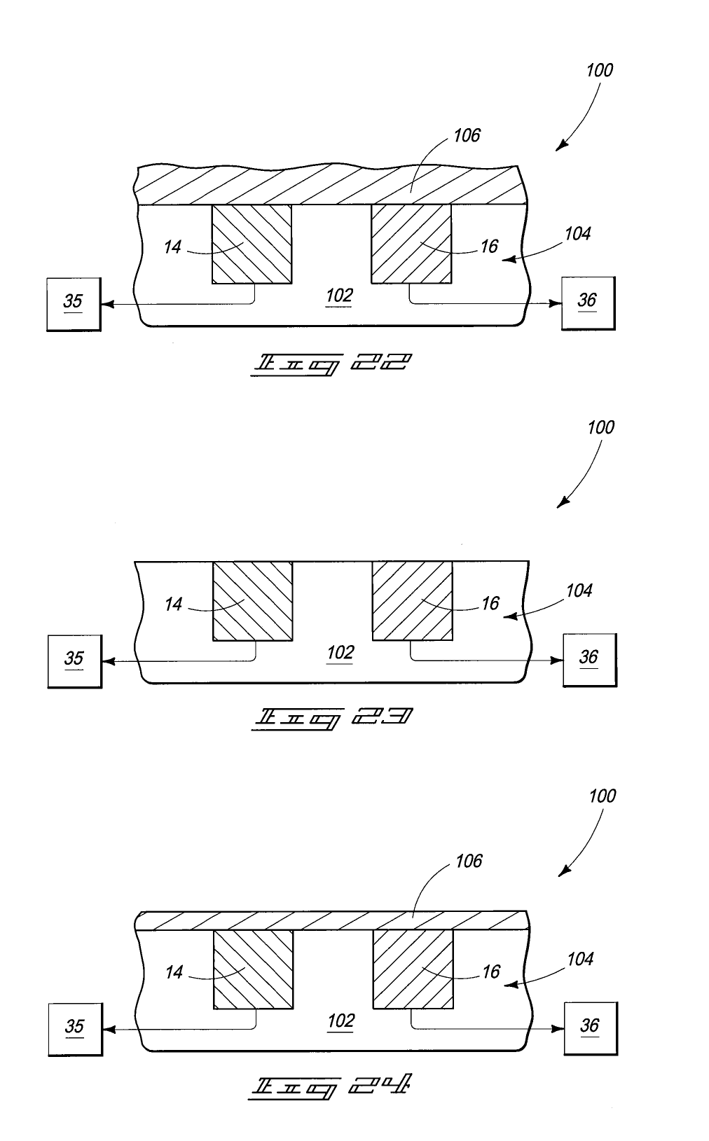

FIG. 23 shows results of CMP that creates the desired planarized surface at the desired level of boundary 61. The CMP removes material 106 from over segments 14 and 16. In contrast, FIG. 24 shows results of under-polishing by the CMP. The material 106 remains over segments 14 and 16. Accordingly, a determination of whether segments 14 and 16 are in the same state as one another (which would indicate that material 106 remains across the segments) or not (which would indicate that the material 106 has been removed from over the segments) may be utilized to ascertain if the CMP has removed material 106 from over the upper surface of substrate 102 or has under-polished material 106. Thus, the test structure 104 may be utilized to quality-test a material removal procedure during a semiconductor fabrication process.

The various procedures described herein may be utilized to form integrated circuit components. Such components may be subsequently incorporated into electronic systems. Such electronic systems may be any of a broad range of systems; including, for example, clocks, televisions, cell phones, personal computers, automobiles, industrial control systems, aircraft, etc.

The particular orientation of the various embodiments in the drawings is for illustrative purposes only, and the embodiments may be rotated relative to the shown orientations in some applications. The description provided herein, and the claims that follow, pertain to any structures that have the described relationships between various features, regardless of whether the structures are in the particular orientation of the drawings, or are rotated relative to such orientation.

When an element is referred to above as being “on” or “against” another element, it can be directly on the other element or intervening elements may also be present. In contrast, when an element is referred to as being “directly on” or “directly against” another element, there are no intervening elements present. When an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

I/we claim:

1. A method for quality testing a material removal procedure during a semiconductor fabrication process, comprising:
forming a test structure comprising a pair of electrically conductive segments; the electrically conductive segments of the test structure being the same relative to a detectable property as long as they are electrically interconnected, but becoming different relative to such property if they are not electrically interconnected; the test structure being utilized solely for quality testing a material removal procedure and having no function in a finished construction formed through the semiconductor fabrication process;
forming material over the test structure, and across a region of a semiconductor substrate proximate to the test structure;
subjecting the material to a procedure which removes at least some of the material, the procedure being part of a semiconductor fabrication process in the region proximate to the test structure; and
after the procedure, determining if the electrically conductive segments remain the same as one another in the detectable property to ascertain if the material has been appropriately removed during the procedure.

2. The method of claim 1 wherein the detectable property is secondary electron emission.

3. The method of claim 1 wherein the detectable property is an electrical state.

4. The method of claim 1 wherein the semiconductor fabrication process forms a plurality of separate semiconductor dies from die locations of a semiconductor wafer; wherein the wafer has scribe regions between the die locations, and wherein the test structure is formed only within the scribe regions.

5. The method of claim 1 wherein the test structure includes a patterned electrical jumper extending across the segments and electrically interconnecting the segments to one another.

6. The method of claim 5 wherein the quality testing is to detect under-etching, and wherein the under-etching is detected by a failure to break the jumper.

7. The method of claim 5 wherein the quality testing is to detect over-etching, and wherein the over-etching is detected by a broken jumper.

8. The method of claim 1 wherein the material removal procedure is chemical-mechanical polishing.

9. The method of claim 1 wherein the electrically conductive segments are parallel lines.

10. The method of claim 1 wherein the electrically conductive segments are a same composition as one another.

11. The method of claim 10 wherein the electrically conductive segments comprise metallic material.

12. A method for quality testing a polishing process during a semiconductor fabrication process, comprising:
forming a first stack of materials over a die location of a semiconductor wafer, with an uppermost material of such stack being a material which is to be removed by chemical-mechanical polishing; the semiconductor wafer having a scribe region proximate to the die location;
forming a second stack of materials within the scribe region, the second stack of materials being the same as the first stack of materials except that a test structure is formed directly under said uppermost material; the test structure comprising a conductive jumper across a pair of electrically conductive segments; the electrically conductive segments of the test structure being the same relative to a detectable property as long as the jumper electrically connects them, but become different relative to such property if the jumper does not connect them; the test structure being formed only within the scribe regions;
utilizing chemical-mechanical polishing to attempt to remove the uppermost material; and
after attempting to remove the uppermost material, determining if the electrically conductive segments of the test structure remain the same as one another in the detectable property to ascertain if the jumper has been broken by the chemical-mechanical polishing, and to thereby determine if the chemical-mechanical polishing has completely removed the uppermost material.

13. The method of claim 12 wherein the detectable property is secondary electron emission.

14. The method of claim 12 wherein the detectable property is an electrical state.

15. The method of claim 12 further comprising, after determining if the electrically conductive segments of the test structure remain the same as one another, sawing through the scribe region.

16. A semiconductor wafer construction, comprising:
a semiconductor wafer subdivided amongst a plurality of die locations and a plurality of scribe regions between the die locations;
at least one test structure within at least one of the scribe regions; the test structure being entirely contained within said at least one of the scribe regions; the test structure comprising a pair of electrically conductive segments; the electrically conductive segments being identical to one another relative to a detectable property as long as the they are electrically connected to one another, but being distinguishable from one another relative to such detectable property if they are not electrically connected to one another.

17. The construction of claim 16 wherein the detectable property is secondary electron emission.

18. The construction of claim 16 wherein the detectable property is a voltage state.

19. The construction of claim 16 wherein the electrically conductive segments are a same composition as one another.

20. The construction of claim 16 further comprising an electrically conductive jumper extending across the electrically conductive segments to electrically connect the segments with one another.
